(19) United States
(12) Patent Application Publication
(10) Pub. No.: US 2012/0087516 A1
(43) Pub. Date: Apr. 12, 2012

(54) SYSTEM AND METHODS FOR DYNAMICALLY CONTROLLING ATLEAST A MEDIA CONTENT WITH CHANGES IN AMBIENT NOISE

(76) Inventor: Umesh AMIN, Redmond, WA (US)

(21) Appl. No.: 13/269,590

(22) Filed: Oct. 8, 2011

Related U.S. Application Data
(60) Provisional application No. 61/391,222, filed on Oct. 8, 2010.

(51) Int. Cl. H03G 3/00

(52) U.S. Cl. 381/107

(57) ABSTRACT

Disclosed are methods and system method for dynamically maintaining at least an output volume of a media system at a predefined volume level in response to at least a change in an instantaneous ambient noise level. The method comprises the steps of: establishing the predefined volume level of the media system; measuring at least the change in the instantaneous ambient noise level; and adjusting dynamically the output volume of the media system against at least the change in the instantaneous ambient noise level to maintain the predefined volume level for a constant media experience.

### CROSS-REFERENCE TO RELATED APPLICATION

This non-provisional patent application claims priority from the U.S. provisional patent application Ser. No. 61/391,222 filed on Oct. 08, 2010, the content of which is incorporated herein by reference.

### FIELD OF THE INVENTION

The present invention relates generally to controlling media content, and more particularly, to system and methods for dynamic volume control of sound output in response to the changes in the ambient noise in a secure, efficient, cost effective, and user friendly manner.

### BACKGROUND OF THE INVENTION

There are many volume control mechanisms developed and practiced to provide user preferred volume for audio output for consumer electronics. All TVs, mobile phones, gaming consoles, radios, MP3 players, computers, car stereos, audio amplifiers, DVD players, set-top boxes, home theater systems, and other media appliances have a knob or a switch in the control panel to allow the users to adjust the volume level manually in response to the change in the ambient noise. Most of these appliances have a wireless remote control that facilitates the sound adjustment as well. Many of the portable appliances support ambient noise suppression techniques at the device microphone. In some instances, volume level is controlled by the content and is dynamically adjusted. There are wireless TV head-sets developed to support hearing impaired overcome the ambient noise problem by manually adjusting the volume for their headsets.

In some automobile stereos, the car computer may be monitoring the speed and engine performance to adjust the stereo volume. In some automobiles with navigation system or built-in mobile phone systems, when the navigation announcement is played or if the mobile phone is in operation, the rest of the audio system volume is reduced or suppressed. In mobile phones, ambient noise reduction or cancellation microphones are used to effectively capture the intelligible components of the user voice over the noise. This alleviates the need for the called party to increase the volume to listen to the caller.

While all the conventional volume control systems and processes do an adequate job in providing volume control, in most appliances including audio systems, however, there is no mechanism to measure change in instantaneous ambient noise level for providing dynamic volume control/adjustment based on the changes on the instantaneous ambient noise level Accordingly, the existing means for volume control fail to provide a consistent listening experience to a user in reference to the instantaneous ambient noise changes.

In view of the disadvantages inherent in the conventional means of volume control, it has remained a constant concern to provide for more practical, more efficient cost effective means by which volume is dynamically adjusted without any user intervention and the same intelligibility of the sound is maintained with the change in the ambient noise.

### SUMMARY FOR THE INVENTION

In view of the foregoing disadvantages inherent in the prior art, the general purpose of the present invention is to provide an improved combination of convenience and utility by which emergency ambient sounds or notifications may be recognized to dynamically adjust an output volume of a media system to maintain same intelligibility of the sound without any user intervention and to alert the listener about potential danger by an emergency notification; to include advantages of the prior art and to overcome the drawbacks inherent therein.

In one aspect, the present invention provides a method for dynamically maintaining at least an output volume of a media system at a predefined volume level in response to at least a change in an instantaneous ambient noise level. The method comprises the steps of: establishing the predefined volume level of the media system; measuring at least the change in the instantaneous ambient noise level; and adjusting dynamically the output volume of the media system against at least the change in the instantaneous ambient noise level to maintain the predefined volume level for a constant media experience.

In another aspect, the present invention provides a method for rendering at least an emergency notification by dynamically adjusting presentation of at least a running media content of a media system in response to at least an instantaneous emergency ambient sound. The method comprises the steps of: establishing a predefined volume level of the media system; measuring an instantaneous emergency ambient sound level; and altering dynamically the presentation of the running media content in at least one of presence of the instantaneous emergency ambient sound and after vanishing of the emergency ambient sound.

In another aspect, the present invention provides a system for dynamically maintaining an output volume of a media system at a predefined volume level in response to at least a change in an instantaneous ambient noise level. The system comprises: at least a controller adapted to at least monitor the instantaneous ambient noise level and to dynamically adjust the output volume of the media system at at least a predefined volume level; at least a sound processor adapted to continuously monitor at least one of the instantaneous ambient noise level and an emergency ambient sound level for providing at least a measurement of at least one of the instantaneous ambient noise level and the emergency ambient sound level to the controller; and at least an output means adapted to render at least an output media.

These together with other aspects of the present invention, along with the various features of novelty that characterize the invention, are pointed out with particularity in the detailed description forming a part of this disclosure. For a better understanding of the present invention, its operating advantages, and the specific objects attained by its uses, reference should be made to the accompanying drawings and descriptive matter in which there are illustrated exemplary embodiments of the present invention.

### BRIEF DESCRIPTION OF THE DRAWINGS

While the specification concludes with claims that particularly point out and distinctly claim the present invention, it is believed the expressly disclosed exemplary embodiments of the present invention can be well understood from the following detailed description taken in conjunction with the accompanying drawings, in which like reference numerals identify the same elements. The drawings and detailed description which follow are intended to be merely illustrative of the expressly disclosed exemplary embodiments and are not intended to limit the scope of the invention as set forth in the appended claims. In the drawings:

FIG. 1 illustrates a flow graph of a method for dynamically maintaining at least an output volume of a media system at a predefined volume level in response to at least a change in an instantaneous ambient noise level, according to an exemplary embodiment of the present invention;

FIG. 2 illustrates a flow graph of a method for rendering at least an emergency notification by dynamically adjusting presentation of at least a running media content of a media system in response to at least an instantaneous emergency ambient sound, according to an exemplary embodiment of the present invention;

FIG. 3 illustrates a flow graph of a method for dynamic volume control for sound output in response to the changes in the ambient noise, according to an exemplary embodiment of the present invention; and

FIG. 4 illustrates a system for dynamically maintaining an output volume of a media system at a predefined volume level in response to at least a change in an instantaneous ambient noise level, according to an exemplary embodiment of the present invention.

Like reference numerals refer to like parts throughout several views of the drawings of the present invention.

### DETAILED DESCRIPTION OF THE INVENTION

The exemplary embodiments of the present invention, described herein detail for illustrative purposes, are subject to many variations, structure and design. It should be emphasized, however that the present invention is not limited to particular system or methods for dynamic volume control for maintaining a predefined level of sound output for the constant listening experience or to alert the listener about potential danger by an emergency notification without any user intervention in response to the changes in the ambient noise or emergency ambient sounds, as shown and described. On the contrary, a person skilled in the art will appreciate that many other embodiments of the present invention are possible without deviating from the basic concept of the present invention as the principles of the present invention can be used with a variety of dynamic volume control for sound output methods and structural arrangements. It is understood that various omissions, substitutions of equivalents are contemplated as circumstances may suggest or render expedient, but the present invention is intended to cover such alternatives, modifications, and equivalents as can be reasonably included within the scope of the present invention and any such work around will also fall under scope of the present invention without departing from the spirit or scope of the its claims.

In the following description, for purposes of explanation, numerous specific details are set forth in order to provide a thorough understanding of the present invention. It will be apparent, however, to one skilled in the art that the present invention may be practiced without these specific details.

As used herein, the term ‘plurality’ refers to the presence of more than one of the referenced item and the terms ‘a’, ‘an’, and ‘at least’ do not denote a limitation of quantity, but rather denote the presence of at least one of the referenced item. The term ‘system also includes ‘engine’, ‘machine’, ‘device’, and ‘apparatus’.

The terms ‘audio device’, ‘video device’, ‘media system’ and ‘media device’ may also be used herein interchangeably. The media device may be of any device capable of communicating media contents. The term ‘communicating’ also includes displaying. The media content may include at least one of an audio, a video or both audio and video.

According to an exemplary embodiment, the present invention provides more practical and more efficient cost effective means by which volume of a media system is dynamically adjusted at a predefined level without any user intervention with same intelligibility of the sound with the change in the ambient noise level so that the listener can maintain the constant volume experience and/or the listener may also be alerted about potential danger by an emergency notification, in an easy, secure, efficient, cost effective, and environment friendly manner.

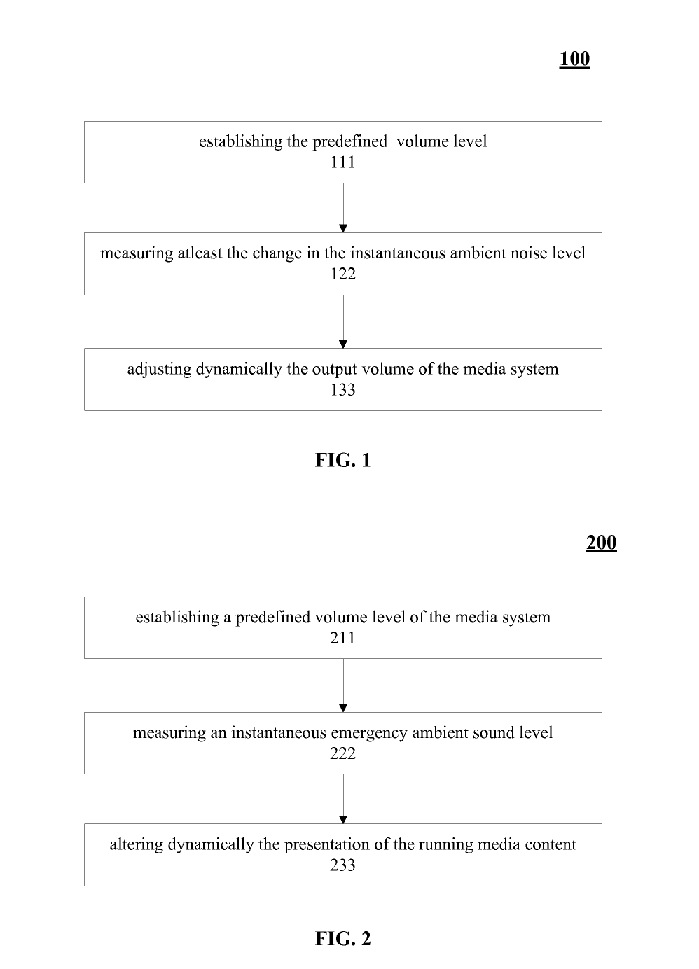

Referring to FIG. 1 which illustrates a flow graph of a method 100 for dynamically maintaining at least an output volume of a media system 20 at a predefined volume level in response to at least a change in an instantaneous ambient noise level, according to an exemplary embodiment of the present invention. The method 100 comprises the steps of: establishing the predefined volume level of the media system 20 at a step 111; measuring at least the change in the instantaneous ambient noise level at a step 122; and adjusting dynamically the output volume of the media system 20 against at least the change in the instantaneous ambient noise level to maintain the predefined volume level for a constant media experience at a step 133. The step 111 of establishing the predefined volume level of the media system 20 may further comprise the step of measuring at least the instantaneous ambient noise level and an instantaneous volume level of the media system 20.

According to an exemplary embodiment of the present invention, the method 100 may further comprise the step of updating the predefined volume level of the media system 20 against the instantaneous ambient noise if the predefined volume level of the media system is changed manually.

According to an exemplary embodiment of the present invention, at least one of a microphone of the media systems, a mobile phone microphone, MP-3 player microphone, MP-4 player microphone, a TV Microphone, a wireless remote microphone, an I-Pad, a tablet PC, a car media system sensors, a game console sensor, a home theatre sensor, a set-top box sensor, other noise measuring devices or any combination thereof may be adapted to measure the instantaneous ambient noise level.

The ambient noise includes at least one of instantaneous notification sound, specific frequencies, tones, sounds, waves, an emergency light, an emergency ambient sound, a fire alarm, a siren, a vehicle honking, emergency warning sound including police vehicle warning sound, an ambulance siren, thunder sound, explosion sound, cracker sound or any combination thereof.

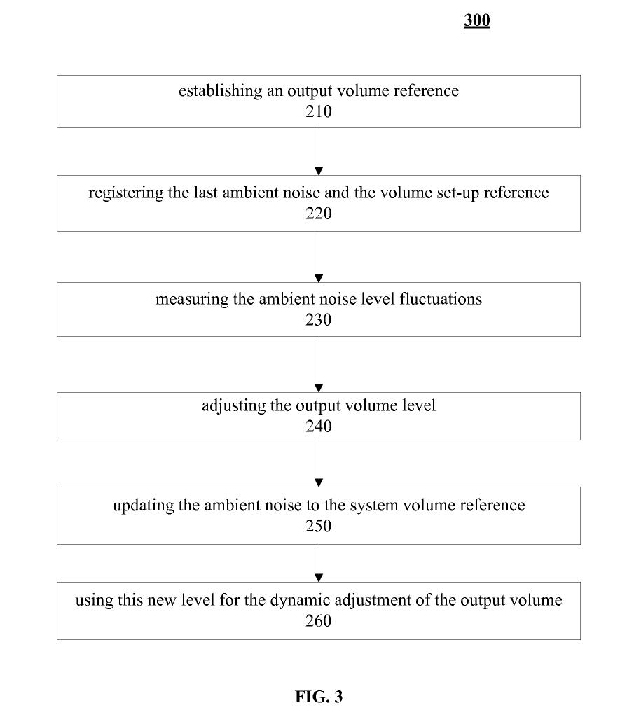

Referring to FIG. 2 which illustrates a flow graph of a method 200 for rendering at least an emergency notification by dynamically adjusting presentation of at least a running media content of a media system 20 in response to at least an instantaneous emergency ambient sound, according to an exemplary embodiment of the present invention. The method 200 comprises the steps of: establishing a predefined volume level of the media system 20 at a step 211; measuring an instantaneous emergency ambient sound level; and altering dynamically the presentation of the running media content in at least one of presence of the instantaneous emergency ambient sound and after vanishing of the emergency ambient sound at a step 233.

According to an exemplary embodiment of the present invention, the step 233 of altering dynamically the presentation of the running media content includes at least one of adjusting dynamically volume to low or high, rendering of special alert messages, rendering emergency notification media content, rendering of special alert images, rendering of warning messages, pausing of running media contents, resuming playing of an original media content at the predefined volume level once the instantaneous emergency ambient sound vanishes or any combination thereof.

According to an exemplary embodiment of the present invention, at least one of an external microphone of the media systems, a mobile phone microphone, MP-3 player microphone, MP-4 player microphone, a car media system sensor, a game console sensor, a home theatre sensor, a set-top box sensor or any combination thereof may be adapted to measure the instantaneous emergency ambient sound level.

Referring to FIG. 3 which illustrates a flow graph of an exemplary method 300 for dynamic volume control for sound output in response to the changes in the ambient noise, according to an aspect of the present invention. The method 300 comprises the steps of: establishing an output volume reference for the media system 20 at a step 210; registering the last ambient noise and the volume set-up reference to establish the ambient noise level to the system volume reference at a step 220, wherein the controller 12 starts once the reference is established; measuring the ambient noise level fluctuations through the sound processor 14 at a step 230; adjusting the output volume level at a step 240; updating the ambient noise to the system volume reference (predefined volume level) if the user makes any manual change to the volume at a step 250; and using this new level for the dynamic adjustment of the output volume at a step 260.

According to an exemplary embodiment, system 10 and methods 100, 200 and 300 of the present invention are capable of pausing the current content being played and dynamically substitute the output content with emergency sound in response to the presence of emergency sound. Once the emergency sound vanishes, a method is used to resume playing of the original content at the reference volume level.

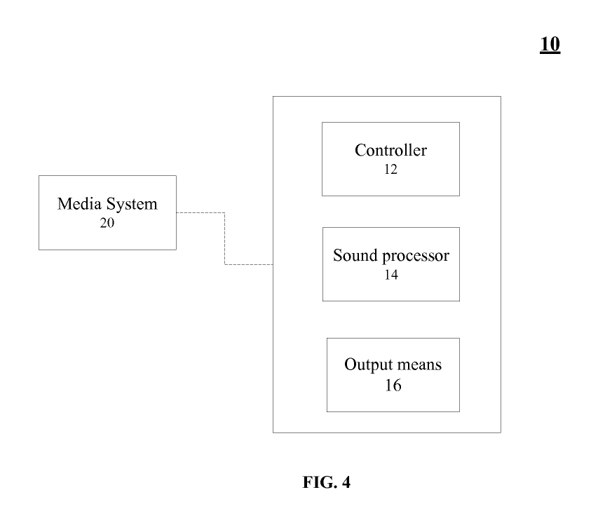

Referring to FIG. 4 which illustrates a system 10 for dynamically maintaining an output volume of a media system 20 at a predefined volume level in response to at least a change in an instantaneous ambient noise level, according to an exemplary embodiment of the present invention. The system 10 comprises: at least a controller 12 adapted to at least monitor the instantaneous ambient noise level and to dynamically adjust the output volume of the media system 20 at at least a predefined volume level; at least a sound processor 14 adapted to continuously monitor at least one of the instantaneous ambient noise level and an emergency sound level for providing at least a measurement of at least one of the instantaneous ambient noise level and the emergency sound level to the controller 12; and at least an output means 16 adapted to render at least an output media. The output means 16 may includes speakers, display screen, other output devices capable of rendering or displaying or communicating at least a media content.

According to an exemplary embodiment of the present invention, the controller 12 may be connected with the audio input, audio output, and ambient noise measurement mechanism. Based on the user adjusted volume level and the instantaneous ambient noise level, the controller 12 may first sets the reference or predefined volume level. The controller 12 may constantly measure the ambient noise or emergency ambient sound notifications and dynamically adjusts the audio out volume level to maintain the constant listening experience for the user.

According to an exemplary embodiment of the present invention, the sound processor 14 includes at least one of an audio noise sensor, a microphone, microphone of a mobile phone, a TV microphone, a PC microphone, a wireless remote microphone, car ambient noise and vibration sensor, audio sensor in the game console, home theatre audio sensor, a media sensor or any combination thereof.

The media system 20 may includes at least one of a remote control operable televisions, DVD players, audio amplifier systems, MP3 players, car stereos, mobile phones, home theaters, computers, set-top boxes, tablet PC, i-pads, laptops, CD players, and other media appliances capable of running and rendering media content or any combination thereof.

According to an exemplary embodiment of the present invention, commercially available ambient noise measurement apparatus may be adapted for linking the measured ambient noise against the predefined or reference volume and making adjustment to maintain the output volume of the media system 20 at a predefined level to provide the constant listening experience to the user.

According to an exemplary embodiment of the present invention, the sound processor 14 is capable of being integrated with at least a portable media player to at least one of recognizing the ambient noise, to providing an ambient noise feedback to the media system 20 for a dynamical adjustment of the volume, to alerting the listener about potential danger by over riding the media system volume with an emergency notification sound. The portable medial player may include at least one of MP3 players, MP-4 players, remote control, media controller mobile phones or any combination thereof.

According to an exemplary embodiment of the present invention, the system 10 may be provided as plug-in system, as an accessory to existing media or communication system or an integral part thereof. The system 10 may also be provided as additional unit. Further, the present invention is capable of using existing ambient noise measurement sub-system.

According to an exemplary embodiment of the present invention, at least one of the controller 12, sound processor 14, the output means 16 or any combination thereof may be adapted as an additional elements of the media system 20 with enhancement or be part of a larger media systems or subsystems for the exemplary embodiment to work correctly. The controller 12 is capable of dynamically adjusting the media content, for example, audio output volume, against an earlier reference or predefined volume to maintain a constant volume experience for the listener.

According to an exemplary embodiment of the present invention, in addition to the above mentioned functionality, the controller 12 is capable of monitoring the ambient noise for specific frequencies or tones or sound which are associated with the emergency notification (e.g. fire alarm, siren, vehicle honking, police car emergency warning sound, etc.) to reduce the output volume dramatically so that the listener can hear the warning. Once the emergency notification sounds have vanished, the controller 12 may resume the normal output volume level at the predefined/reference level. In addition to the physical elements, there may be a method and logical procedure that may be useful to monitor the ambient noise and emergency notifications for dynamically adjusting the volume of the media system 20 to maintain the reference volume level.

According to an exemplary embodiment of the present invention, the sound processor 14 may be adapted to continuously measure the ambient noise level and provide the measurements to the controller 12, so that the controller 12 may first establish output volume reference (also referred to as ‘predefined volume level’) and then dynamically adjust the output volume against the earlier reference volume in such a way that the constant volume experience is maintained for the listener. In mobile phones, such functionality may be accomplished by the use of the current microphone as the sound processor 14 or a new audio sensor may be introduced to achieve this function. In other audio systems with remote control (TV, DVD Players, audio amplifier systems, CD players, etc), the sound processor 14 may be designed into the remote control and the ambient noise feedback may be provided from the remote control to the media system 20 for the dynamical adjustment of the volume.

According to an exemplary embodiment of the present invention, in portable MP3 players or a mobile phone with a built in media player, the sound processor 14 may be added to the existing design to accomplish an exemplary embodiment of the present invention, for example, in portable MP3 players or the mobile phone with built in media player, the sound processor 14 may also recognize the police siren and other warning sounds (e.g. car honking) to alert the listener about potential danger by over riding the system volume with the emergency warning sounds.

Generally, most of the conventional media systems, for example, audio systems, comprise of audio input, audio output, and audio controller function. The present invention is capable of providing the automated measurements and feedback mechanism to adjust the audio volume in reference to the ambient noise.

According to an exemplary embodiment of the present invention, in media systems 10 where an external microphone exists, the ambient noise measurements may be made from that microphone instead of adding an additional ambient noise measurement device, for example, in a cell phone system, the ambient noise may be measured from the microphone.

According to an exemplary embodiment, the present invention may permit the user to set the initial volume for the sound output and maintain the same intelligibility by automatically adjusting volume up or down as it receives the ambient noise feedback and thereby maintains the constant sound volume experience for the end user from the intelligibility perspective. For example, a person is driving a car in the urban city neighborhood and has a radio on at volume level 5. Now, as they change the driving environment from the city driving to highway driving during the same contiguous drive, the ambient car noise is much higher, and the car stereo would increase the volume automatically to maintain the same intelligibility of the car stereo sound output that was there in the urban city neighborhood drive at volume 5. The converse would also be true and this dynamic volume control may provide same constant volume sound experience without any user intervention if the ambient noise decreases.

According to an exemplary embodiment of the present invention, based on the ambient noise type, the media appliance may automatically reduce the volume dramatically or mute the volume so that the listener can comprehend the ambient noise and act accordingly. For example, a person is driving a car with the stereo on. If the police siren or an ambulance siren is in the ambient noise, the stereo volume is automatically reduced dramatically so that the driver can hear the siren and safely drive the car out of the direct path of an emergency response vehicle. Similarly, in a case of a pedestrian listening to an MP3 player or a mobile phone while walking in the vicinity of ambient emergency caution sound (e.g. car horn or police siren) would experience automatic reduction in the volume or the player content being paused and over ridden by the emergency sound so that they can here the caution sound and react safely.

According to an exemplary embodiment, the present invention may be implemented with accessories and attachments for the existing and future audio systems. A most plausible scenario is for expensive sound systems where replacement cost is significantly higher. In those cases, the system manufacturers or the third party accessories developer may provide benefit of this invention, for example, a company may develop a new remote control that embodies the present invention with audio sensor for ambient noise and dynamically making the volume adjustment request to the audio appliance it controls.

In various exemplary embodiments of the present invention, the operations discussed herein, e.g., with reference to FIGS. 1 to 4, may be implemented through computing devices such as hardware, software, firmware, or combinations thereof, which may be provided as a computer program product, e.g., including a machine-readable or computer-readable medium having stored thereon instructions or software procedures used to program a computer to perform a process discussed herein. The machine-readable medium may include a storage device. For example, the operation of components of the system 10 and methods 100, 200, 300 may be controlled by such machine-readable medium.

In other instances, well-known methods, procedures, components, and circuits have not been described herein so as not to obscure the particular embodiments of the present invention. Further, various aspects of embodiments of the present invention may be performed using various means, such as integrated semiconductor circuits, computer-readable instructions organized into one or more programs, or some combination of hardware and software.

Although particular exemplary embodiments of the present invention has been disclosed in detail for illustrative purposes, it will be recognized to those skilled in the art that variations or modifications of the disclosed invention, including the rearrangement in the configurations of the parts, changes in sizes and dimensions, variances in terms of shape may be possible. Accordingly, the invention is intended to embrace all such alternatives, modifications and variations as may fall within the spirit and scope of the present invention.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is understood that various omissions, substitutions of equivalents are contemplated as circumstance may suggest or render expedient, but is intended to cover the application or implementation without departing from the spirit or scope of the claims of the present invention.

What is claimed is:

1. A method for dynamically maintaining at least an output volume of a media system at a predefined volume level in response to at least a change in an instantaneous ambient noise level, comprising the steps of:
establishing the predefined volume level of the media system;
measuring at least the change in the instantaneous ambient noise level; and
adjusting dynamically the output volume of the media system against at least the change in the instantaneous ambient noise level to maintain the predefined volume level for a constant media experience.

2. The method of claim 1 wherein the step of establishing the predefined volume level of the media system further comprising the step of measuring at least the instantaneous ambient noise level and an instantaneous volume level of the media system.

3. The method of claim 1 further comprising the step of updating the predefined volume level of the media system against the instantaneous ambient noise if the predefined volume level of the media system is changed manually.

4. The method of claim 1, wherein the media system is capable of communicating at least a media contents including at least one of an audio and a video.

5. The method of claim 1, wherein at least one of a microphone of the media systems, a mobile phone microphone, a MP-3 player microphone, a TV Microphone, a wireless remote microphone, a MP-4 player microphone, an I-Pad, a tablet PC, a car media system sensors, a game console sensor, a home theatre sensor, a set-top box sensor or any combination thereof is adapted to measure the instantaneous ambient noise level.

6. A method for rendering at least an emergency notification by dynamically adjusting presentation of at least a running media content of a media system in response to at least an instantaneous emergency ambient sound, comprising the steps of:
establishing a predefined volume level of the media system;
measuring an instantaneous emergency ambient sound level; and
altering dynamically the presentation of the running media content in at least one of presence of the instantaneous emergency ambient sound and after vanishing of the emergency ambient sound.

7. The method of claim 6, wherein the step of altering dynamically the presentation of the running media content includes at least one of adjusting dynamically volume to low or high, rendering of special alert messages, rendering emergency notification media content, rendering of special alert images, rendering of warning messages, pausing of running media contents, resuming playing of an original media content at the predefined volume level once the instantaneous emergency ambient sound vanishes or any combination thereof.

8. The method of claim 6, wherein the media system is capable of communicating at least a media content including at least one of an audio and a video.

9. The method of claim 6, wherein at least one of an external microphone of the media systems, a mobile phone microphone, a MP-3 player microphone, a TV microphone, a PC microphone, a wireless remote microphone, a MP-4 player microphone, a car media system sensor, a game console sensor, a home theatre sensor, a set-top box sensor or any combination thereof is adapted to measure the instantaneous emergency sound level.

10. A system for dynamically maintaining an output volume of a media system at a predefined volume level in response to at least a change in an instantaneous ambient noise level, comprising:
at least a controller adapted to at least monitor the instantaneous ambient noise level and to dynamically adjust the output volume of the media system at at least a predefined volume level;
at least a sound processor adapted to continuously monitor at least one of the instantaneous ambient noise level and an emergency ambient sound level for providing at least a measurement of at least one of the instantaneous ambient noise level and the emergency ambient sound level to the controller; and
at least an output means adapted to render at least an output media.

11. The system of claim 10, wherein the ambient noise includes at least one of instantaneous notification sound, specific frequencies, tones, sounds, waves, an emergency light, an emergency ambient sound, a fire alarm, a siren, a vehicle honking, an emergency warning sound including police vehicle warning sound, an ambulance siren, thunder sound, an explosion sound, a cracker sound or any combination thereof.

12. The system of claim 10, wherein the sound processor includes at least one of an audio noise sensor, a microphone, a TV microphone, a PC microphone, a wireless remote microphone, a microphone of a mobile phone, a car ambient noise and vibration sensor, an audio sensor in the game console, a home theatre audio sensor, a media sensor or any combination thereof.

13. The system of claim 10, wherein the sound processor is capable of being integrated with at least a portable media player to recognize the ambient noise and alert the listener about potential danger by over riding the media system volume with an emergency notification sound, wherein the portable medial player include at least one of MP3 players, MP-4 players, remote control, media controller mobile phones or any combination thereof.
